(19) United States
(12) Patent Application Publication
(10) Pub. No.: US 2025/0228028 A1
(43) Pub. Date: Jul. 10, 2025

(54) IMAGE SENSOR AND MANUFACTURING METHOD OF THE SAME

(71) Applicant: Samsung Electronics Co., Ltd., Suwon-si (KR)

(72) Inventor: Sejin PARK, Suwon-si (KR)

(73) Assignee: Samsung Electronics Co., Ltd., Suwon-si (KR)

(21) Appl. No.: 18/813,227

(22) Filed: Aug. 23, 2024

(30) Foreign Application Priority Data
Jan. 10, 2024 (KR) 10-2024-0004409

(51) Int. Cl. H01L 27/146

(52) U.S. Cl. CPC H10F 39/811; H10F 39/024; H10F 39/8053; H10F 39/8057; H10F 39/8063; H10F 39/807

(57) ABSTRACT

An image sensor according to various example embodiments includes a photoelectric conversion substrate including a photoelectric conversion portion, a light receiving portion on a surface of the photoelectric conversion substrate, and a bonding layer that bonds the photoelectric conversion substrate and the light receiving portion between the photoelectric conversion substrate and the light receiving portion.

### CROSS-REFERENCE TO RELATED APPLICATION

This application claims priority to and the benefit of Korean Patent Application No. 10-2024-0004409 filed in the Korean Intellectual Property Office on Jan. 10, 2024, the entire contents of which are incorporated herein by reference.

### BACKGROUND

Various example embodiments relate to an image sensor and/or a manufacturing method of the same, and more particularly, to an image sensor with improved structure and integration and/or a manufacturing method of the same.

An image sensor is or includes a semiconductor device that converts optical images into electrical signals. The image sensors may be classified into charge coupled device (CCD) type image sensors based on silicon semiconductors and complementary metal oxide semiconductor (CMOS) type image sensors (CIS).

Among these, the CMOS type image sensor may be driven by a simple method. Alternatively or additionally, a signal processing circuit may be integrated on a single chip in the CMOS type image sensor. Therefore, the CMOS type image sensor may be downsized and have a low power consumption, and thus, may be applied to products with a limited battery capacity. With the advancement of the electron industry, various studies are continuing to improve the performance of the CMOS type image sensors.

### SUMMARY

Various example embodiments attempt to provide an image sensor having enhanced properties and/or various functions. Alternatively or additionally, various example embodiments attempt to provide an image sensor capable of diversifying a manufacturing process, and/or a manufacturing method of the same.

An image sensor according to some example embodiments includes a photoelectric conversion substrate including a photoelectric conversion portion, a light receiving portion on a surface of the photoelectric conversion substrate, and a bonding layer bonding the photoelectric conversion substrate and the light receiving portion between the photoelectric conversion substrate and the light receiving portion.

Alternatively or additionally an image sensor according to various example embodiments includes a photoelectric conversion substrate including a photoelectric conversion portion, and a light receiving portion on a surface of the photoelectric conversion substrate. The light receiving portion includes a first portion including a pattern portion and a planarization layer covering the pattern portion. The pattern portion is at a side of a first surface of the first portion opposite to the photoelectric conversion substrate, and the planarization layer is at a side of a second surface of the first portion closer to the photoelectric conversion substrate.

Alternatively or additionally according to various example embodiments, a manufacturing method of an image sensor includes preparing a preliminary substrate and a photoelectric conversion substrate, bonding the preliminary substrate and the photoelectric conversion substrate, and removing a carrier substrate. In the preparing of the preliminary substrate and the photoelectric conversion substrate, the preliminary substrate including the carrier substrate and at least a partial portion of a light receiving portion on the carrier substrate is prepared, and the photoelectric conversion substrate including a photoelectric conversion portion is prepared. In the bonding of the preliminary substrate and the photoelectric conversion substrate, a first bonding layer is formed on the photoelectric conversion substrate, a second bonding layer is formed on the preliminary substrate, and the first bonding layer and the second bonding layer are bonded.

According to various example embodiments, optical properties of an image sensor may be improved and/or functions of the image sensor may be expanded by reducing limitations in a manufacturing process of at least a partial portion of a light receiving portion. Alternatively or additionally, a manufacturing process of at least the partial portion of the light receiving portion may be diversified, and available process conditions and process margins in the manufacturing process of at least the partial portion of the light receiving portion may be expanded. Accordingly, the light receiving portion or the image sensor having enhanced properties and/or various functions may be formed through a suitable or optimized (or improved) process.

### BRIEF DESCRIPTION OF THE DRAWINGS

FIG. 1 is a block diagram schematically illustrating an example of an image sensor.

FIG. 2 is a plan view schematically illustrating a part of an image sensor according to various example embodiments.

FIG. 3 is a cross-sectional view taken along line A-A′ in FIG. 2.

FIG. 4 to FIG. 8 are cross-sectional views schematically illustrating a manufacturing method of an image sensor according to various example embodiments.

FIG. 9 is a cross-sectional view schematically illustrating an image sensor according to a modified embodiment.

FIG. 10 is a cross-sectional view schematically illustrating an image sensor according to a modified embodiment.

FIG. 11 is a cross-sectional view schematically illustrating an image sensor according to various example embodiments.

FIG. 12 and FIG. 13 are cross-sectional views schematically illustrating a manufacturing process of a preliminary substrate included in a manufacturing method of the image sensor illustrated in FIG. 11.

FIG. 14 is a cross-sectional view schematically illustrating an image sensor according to various example embodiments.

FIG. 15 is a cross-sectional view schematically illustrating an image sensor according to various example embodiments.

FIG. 16 is a cross-sectional view schematically illustrating an image sensor according to various example embodiments.

FIG. 17 is a cross-sectional view schematically illustrating an image sensor according to various example embodiments.

### DETAILED DESCRIPTION

Various example embodiments will be described more fully hereinafter with reference to the accompanying drawings for those of ordinary skill in the art to which inventive concepts pertains to easily practice various example embodiments. Inventive concepts may be implemented in various different forms and is not limited to the embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, or so on., illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or so on., may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

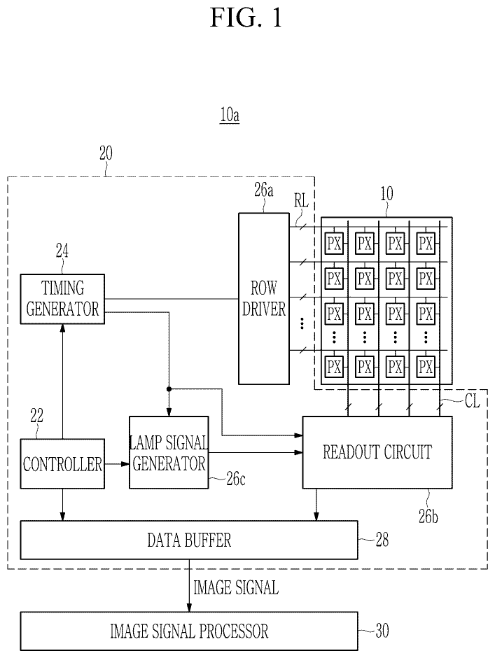

Hereinafter, an image sensor and a manufacturing method of the same according to various example embodiments and a modified embodiment will be described in detail with reference to FIG. 1 to FIG. 10.

FIG. 1 is a block diagram schematically illustrating an example of an image sensor 10a.

Referring to FIG. 1, an image sensor 10a according to various example embodiments may include a pixel array 10, and a logic circuit 20 controlling the pixel array 10. The logic circuit 20 is (or includes) a circuit for controlling the pixel array 10 and may include, for example, a controller 22, a timing generator 24, a row driver 26a, a readout circuit 26b, a lamp signal generator 26c, and a data buffer 28. The image sensor 10a may further include an image signal processor 30. In some example embodiments, the image signal processor 30 may be disposed outside the image sensor 10a.

The image sensor 10a may generate an image signal by converting light received from the outside into an electric signal, and the image signal generated by the image sensor 10a may be provided to the image signal processor 30.

The image sensor 10a may be mounted on an electronic device with an image or light sensing function. For example, the image sensor 10a may be mounted on or be included in electronic devices such as one or more of cameras, smartphones, wearable devices, internet of things (IoT) devices, home appliance devices, tablets, personal digital assistants (PDA), portable multimedia players (PMP), navigations, drones, or advanced driver assistance systems (ADAS). In some example embodiments, the image sensor 10a may be mounted on one or more of a vehicle, a furniture, a manufacturing facility, a door, or an electronic device provided as a part of various measuring devices.

The pixel array 10 may include a plurality of pixel regions PX, and a plurality of row lines RL and a plurality of column lines CL respectively connected to the plurality of pixel regions PX.

In an embodiment, each pixel region PX may include at least one photoelectric conversion device. The photoelectric conversion device may detect incident light and may convert the incident light into the electric signal, for example, a plurality of analog pixel signals, according to an amount of light. The photoelectric conversion device may be or include (or be included in) a photodiode and/or a pinned diode. In some example embodiments the photoelectric conversion device may be or include a single-photon avalanche diode (SPAD) applied to a 3D sensor pixel. The level of the analog pixel signal output from the photoelectric conversion device may be proportional to (e.g., linearly proportional to) the amount of light provided to each pixel region PX or the amount of charge output from the photoelectric conversion device.

The plurality of row lines RL may extend in one direction and be connected to the plurality of pixel regions PX arranged in one direction. For example, a control signal output from the row driver 26a to the row line RL may be transmitted to a gate of a transistor of the plurality of pixel regions PX connected to the row line RL. The column line CL may extend in a direction that is transverse to (or crosses or is perpendicular to) one direction and may be connected to the plurality of pixel regions PX arranged in the direction that is transverse to (or crosses or is perpendicular to) one direction. The plurality of pixel signals output from the plurality of pixel regions PX may be transmitted to the readout circuit 26b through the plurality of column lines CL.

In various example embodiments, the plurality of pixel regions PX may be grouped in a form of a plurality of columns and a plurality of rows to form one unit pixel group. In some cases, a plurality of pixel regions PX arranged in an extension direction of the row line RL and a plurality of pixel regions PX arranged in an extension direction of the column line CL may form one unit pixel group. For example, one unit pixel group includes a plurality of pixels arranged in the form of two columns and two rows, and one unit pixel group may output one analog pixel signal. However, example embodiments are not limited thereto and various modifications are possible.

In various example embodiments, each pixel region PX may include a pixel circuit that processes the charge generated by the photoelectric conversion device and outputs the electric signal. The pixel circuit may include a transmission transistor, a reset transistor, a selection transistor, a driving transistor, or so on. Example embodiments are not limited thereto and the pixel circuit may have various structures. An electrical property and/or a physical characteristic of each transistor may be the same as each other, or, alternatively, may be different from each other; example embodiments are not limited thereto.

The controller 22 may generally control the timing generator 24, the row driver 26a, the readout circuit 26b, the lamp signal generator 26c, and the data buffer 28 included in the image sensor 10a. For example, the controller 22 may control an operation timing by using a control signal. In various example embodiments, the controller 22 may receive a mode signal indicating an imaging mode from an application processor and generally control the image sensor 10a based on the received mode signal.

The timing generator 24 may generate a signal that serves as a reference for the operation timing of the image sensor 10a. The timing generator 24 may provide a control signal that controls the timing of the row driver 26a, the readout circuit 26b, and the lamp signal generator 26c.

The row driver 26a may generate a control signal to drive the pixel array 10 in response to the control signal of the timing generator 24, and may provide the control signal to the plurality of pixel regions PX of the pixel array 10 through the plurality of row lines RL. For example, the row driver 26a may generate one or more of a transmission signal that controls the transmission transistor, a reset control signal that controls the reset transistor, and a selection control signal that controls the selection transistor, and provide the transmission signal, the reset control signal, and the selection signal to the pixel array 10.

The readout circuit 26b may convert a pixel signal (or an electric signal) output through the corresponding column line CL into a pixel value representing the amount of light. The lamp signal generator 26c may generate a reference signal and/or a lamp signal, and may transmit the reference signal or the lamp signal to the readout circuit 26b. For example, the readout circuit 26b may convert the pixel signal to the pixel value by comparing the lamp signal and the pixel signal. The pixel value may be or may include (or be included in) an image data with a plurality of bits.

The data buffer 28 may store the pixel value of the pixel region PX transmitted from the readout circuit 26b and may output the stored pixel value in response to a signal from the controller 22.

The image signal processor 30 may perform an image signal processing on the image signal received from the data buffer 28. For example, the image signal processor 30 may receive a plurality of image signals from the data buffer 28 and may generate one image by combining the received image signals.

Example embodiments are not limited to the above descriptions, and one or more of a structure, a type, or so on of the image sensor 10a may be variously modified.

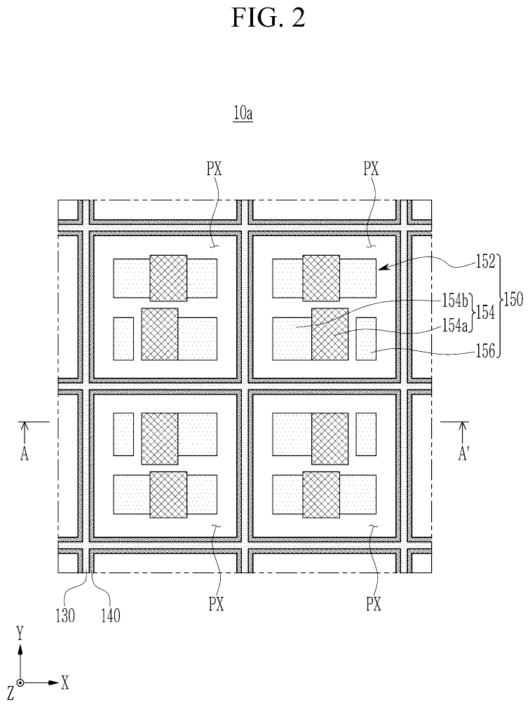

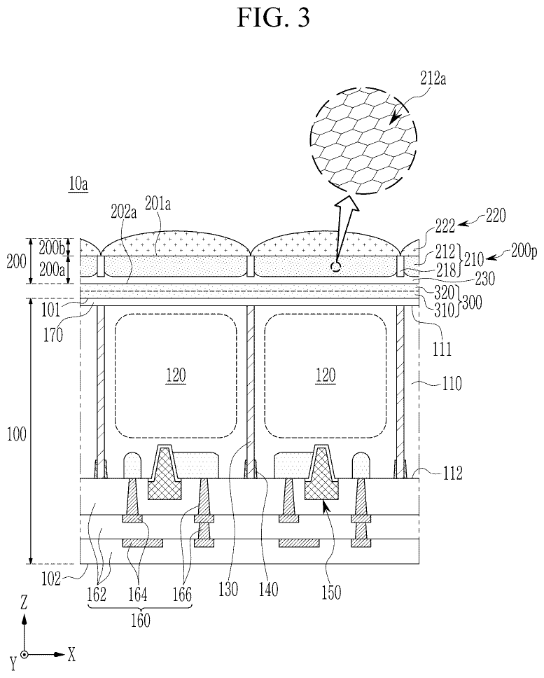

The image sensor 10a (more particularly, the pixel array 10) according to various example embodiments will be described in more detail with reference to FIG. 2 and FIG. 3.

FIG. 2 is a plan view schematically illustrating a part of an image sensor 10a according to various example embodiments. FIG. 3 is a cross-sectional view taken along line A-A′ in FIG. 2. In FIG. 2, a second substrate surface 112 of a substrate 110 adjacent to a wiring portion 160 is illustrated.

Referring to FIG. 2 and FIG. 3, in various example embodiments, an image sensor 10a may include a photoelectric conversion substrate 100, a light receiving portion 200, and a bonding layer 300. The photoelectric conversion substrate 100 may include a photoelectric conversion portion 120. The light receiving portion 200 may be on a first surface 101 of the photoelectric conversion substrate 100. The bonding layer 300 may bond the photoelectric conversion substrate 100 and the light receiving portion 200 between the photoelectric conversion substrate 100 and the light receiving portion 200.

In various example embodiments, the photoelectric conversion substrate 100 may include a substrate 110 including a plurality of pixel regions PX, the photoelectric conversion portion 120 in the substrate 110, a pixel isolation portion 130 defining and/or separating the plurality of pixel regions PX, and a wiring portion 160 at a side of a second surface 102 of the photoelectric conversion substrate 100. The first surface 101 (an upper surface in FIG. 3) of the photoelectric conversion substrate 100 may correspond to a lower surface of the photoelectric conversion substrate 100 in a manufacturing process of the photoelectric conversion substrate 100, and the second surface 102 (a lower surface in FIG. 3) of the photoelectric conversion substrate 100 may correspond to an upper surface of the photoelectric conversion substrate 100 in the manufacturing process of the photoelectric conversion substrate 100.

The substrate 110 may include or be formed of a semiconductor substrate including a semiconductor material. In some example embodiments, the substrate 110 may be doped, e.g., may be lightly doped; however, example embodiments are not limited thereto. For example, the substrate 110 may include a bulk substrate including a semiconductor material, a substrate including a bulk substrate and an epitaxial layer on the bulk substrate, or a semiconductor-on-insulator. In this instance, the semiconductor material included in the substrate 110 may include a first conductivity type dopant to have a first conductivity type (e.g., a P-type or an N-type).

The semiconductor material included in the substrate 110 may include at least one of a group IV semiconductor, a group III-V compound semiconductor, or a group II-VI compound semiconductor. For example, the semiconductor material included in the substrate 110 may include at least one of Si, Ge, SiGe, SiC, GaAs, InAs, GaP, InP, InSb, InGaAs, ZnTe, or CdS. For example, the bulk substrate may be a single crystal or polycrystalline semiconductor substrate and may include one or more of Si, Ge, or SiGe. In some example embodiments, the semiconductor-on-insulator may be or may include one or more of a silicon-on-insulator (SOI), a germanium-on-insulator (GOI), or a silicon-germanium-on-insulator (SGOI).

A first substrate surface 111 (an upper surface in FIG. 3) of the substrate 110 may correspond to a lower surface of the substrate 110 in the manufacturing process of the photoelectric conversion substrate 100, and a second substrate surface 112 (a lower surface in FIG. 3) of the substrate 110 may correspond to an upper surface of the substrate 110 in the manufacturing process of the photoelectric conversion substrate 100.

In various example embodiments, a plurality of pixel regions PX in the substrate 110 may be adjacent to each other in a first direction (an X-axis direction in the drawing) and a second direction (a Y-axis direction in the drawing) that is transverse to the first direction. For example, four pixel regions PX illustrated in FIG. 2 may form one unit pixel group, but example embodiments are not limited thereto.

The photoelectric conversion portion 120 for converting light incident from the outside into an electrical signal may be in the substrate 110. The photoelectric conversion portion 120 may include a second conductivity type dopant to have a second conductivity type (e.g., an N-type or a P-type) opposite to the first conductivity type of the substrate 110.

The substrate 110 and the photoelectric conversion portion 120 may form a photodiode. The photodiode may be formed by a pn junction of the substrate 110 having the first conductivity type and the photoelectric conversion portion 120 having the second conductivity type. The photoelectric conversion portion 120, which constitutes (or is included in) the photodiode, may generate and accumulate charges in proportion to an amount of light provided to each pixel region PX. The charges may be electrons, or may be holes; example embodiments are not limited thereto.

The photoelectric conversion portion 120 may correspond to each pixel region PX by a device isolation portion 140. For example, the device isolation portion 140 may be in a first trench, which has a first depth, to define an active region in each pixel region PX. For example, the first trench may be a shallow trench (ST), and the device isolation portion 140 may be a shallow trench isolation (STI). The device isolation portion 140 may include at least one of silicon oxide, silicon nitride, or silicon oxynitride, and the device isolation portion 140 may include a single layer or a plurality of layers. However, example embodiments are not limited thereto. Therefore, a material of the device isolation portion 140 may be variously modified, or the device isolation portion 140 might not be provided.

The pixel isolation portion 130 may pass through at least a partial portion of the substrate 110 between the plurality of pixel regions PX to define or separate the plurality of pixel regions PX. In this instance, the pixel isolation portion 130 may pass through a partial portion (e.g., a central portion) of the device isolation portion 140.

In various example embodiments, the pixel isolation portion 130 may include a first pixel isolation portion extending in a first direction (the X-axis direction of the drawing) and a second pixel isolation portion extending in a second direction (the Y-axis direction of the drawing). For example, the pixel isolation portion 130 may have a lattice shape that partitions the plurality of pixel regions PX. As a result, each pixel region PX may be surrounded by a pair of first pixel isolation portions and a pair of second pixel isolation portions.

The pixel isolation portion 130 may be in a second trench, which has a second depth greater than the first depth, to define the pixel region PX. For example, the second trench may be a deep trench (DT), and the pixel isolation portion 130 may be a front deep trench isolation (FDTI) formed from the first substrate surface 112 of the substrate 110. For example, the pixel isolation portion 130 may extend from the second substrate surface 112 of the substrate 110 to the first substrate surface 111 of the substrate 110. However, example embodiments are not limited thereto. The pixel isolation portion 130 might not extend to the first substrate surface 111 to be positioned at a partial portion of the substrate 110 in a thickness direction of the substrate 110. In some example embodiments, the pixel isolation portion 130 may further include a back deep trench isolation (BDTI) formed from the first substrate surface 111 of the substrate 110.

In various example embodiments, the pixel isolation portion 130 may include a conductive layer. By applying a negative voltage to the conductive layer of the pixel isolation portion 130, a dark current may be improved through a hole accumulation.

In the drawings, it is illustrated that a surface of the device isolation portion 140 and a surface of the pixel isolation portion 130 adjacent to the second substrate surface 112 of the substrate 110 are on the same plane as the second substrate surface 112 of the substrate 110. However, example embodiments are not limited thereto, and the second substrate surface 112 of the substrate 110, and the surface of the device isolation portion 140 and/or the surface of the pixel isolation portion 130 may be on different planes from each other.

A pixel circuit 150 may be at a side of the second substrate surface 112 of the substrate 110. More particularly, the pixel circuit 150 may be in the pixel region PX defined by the pixel isolation portion 130 and/or the device isolation portion 140. For example, the pixel circuit 150 may include at least one transistor 152, a transmission transistor 154, and a doping region 156.

The transmission transistor 154 may be electrically connected to the photoelectric conversion portion 120. The transmission transistor 154 may include a transmission gate structure 154a and a floating diffusion node or floating diffusion region 154b. The floating diffusion region 154b may have a second conductivity type opposite to the first conductivity type of the substrate 110, and charges generated by the photoelectric conversion portion 120 may be accumulated in (e.g., stored in) the floating diffusion region 154b. The floating diffusion region 154b may be adjacent to at least one side of the transmission gate structure 154a. A shape of the floating diffusion region 154b is not limited as illustrated in FIG. 2 and may be variously modified in some example embodiments.

The transmission gate structure 154a may control the photoelectric device such that the charge generated in the photoelectric conversion portion 120 moves or does not move to the floating diffusion region 154b depending on the applied voltage. The transmission gate structure 154a may include a transmission gate electrode, a gate dielectric layer, and/or a gate spacer.

The transistors 152 may include at least one of a reset transistor, a selection transistor, or a driving transistor included in the pixel circuit. The transistors 152 may include a gate structure and source and drain regions at both sides of the gate structure. For example, the transistors 152 of the plurality of pixel regions PX adjacent to each other may be shared to form the pixel circuit 150.

The doping region 156 may be separated from the floating diffusion region 154b and the transistor 152. The doping region 156 may be doped with a first conductivity type dopant to have the same conductivity type as the first conductivity type of the substrate 110, and a ground voltage may be applied to the doping region 156.

Example embodiments are not limited to the above pixel circuit 150. Therefore, the pixel circuit 150 may have any of various structures or arrangements.

A wiring portion 160 may be on the second substrate surface 112 of the substrate 110 at a side of the second substrate surface 112 of the substrate 110. In some cases, the wiring portion 160 is at the side of the second surface 102 of the photoelectric conversion substrate 100, which is opposite to the light receiving portion 200, and thus, the wiring portion 160 might not be disposed in a path of light incident to the image sensor 10a. As a result, light interference caused by the wiring portion 160 may be minimized.

The wiring portion 160 may include a plurality of wiring layers 164 with an interlayer insulation layer 162 interposed therebetween, and a contact via 166 may pass through the interlayer insulation layer 162 to connect the plurality of wiring layer 164. The wiring layer 164 and the contact via 166 may be connected to form a desired circuit. The contact via 166 may be formed in the same process as the wiring layer 164, or may be formed in a separate process from the wiring layer 164. The wiring portion 160 may be electrically connected to the pixel circuit 150.

The interlayer insulation layer 162 may include an insulating material. For example, the interlayer insulation layer 162 may include one or more of silicon oxide, silicon nitride, silicon oxynitride, or a low dielectric constant material. The low dielectric constant material may be a material having a dielectric constant lower than a dielectric constant of silicon oxide.

The wiring layer 164 or the contact via 166 may include at least one of a metal, a metal alloy, a metal nitride, a metal silicide, or a doped semiconductor material. The metal or the metal alloy may include at least one of tungsten, molybdenum, aluminum, copper, or cobalt, and the metal nitride may include at least one of tungsten nitride, molybdenum nitride, titanium nitride, or tantalum nitride. The wiring layer 164 or the contact via 166 may further include metal oxide or metal oxynitride in which the above material is oxidized. The wiring layer 164 or the contact via 166 may include a single layer or a plurality of layers.

However, example embodiments are not limited to thereto, and the interlayer insulation layer 162 may include any of various insulating materials, and the wiring layer 164 or the contact via 166 may include any of various conductive materials.

In some example embodiments, a support substrate or a logic chip including a logic circuit may be further provided on the wiring portion 160. However, the support substrate might not be provided, or the image sensor 100 may be next to the logic chip. Other various modifications are possible.

More particularly, a horizontal insulation layer 170 may be on the first substrate surface 111 of the substrate 110. The horizontal insulation layer 170 may cover the first substrate surface 111 of the substrate 110 and/or the pixel isolation portion 130.

The horizontal insulation layer 170 may include any of various insulating materials. For example, the horizontal insulation layer 170 may include one or more of oxide, nitride, oxynitride, or fluoride, and may further include one or more of one of hafnium, zirconium, aluminum, tantalum, titanium, yttrium, cerium, lanthanum, neodymium, praseodymium, ytterbium, or silicon. For example, the horizontal insulation layer 170 may serve as an anti-reflection layer, but example embodiments are not limited thereto.

In various example embodiments, the horizontal insulation layer 170 may include a plurality of layers including different materials and/or may have different thicknesses. For example, in the horizontal insulation layer 170, a first horizontal insulation layer adjacent to the first substrate surface 111 of the substrate 110 may be a fixed charge layer having a negative fixed charge. Thereby, the dark current may be improved by a hole accumulation at a periphery of the fixed charge layer. In various example embodiments, the first horizontal insulation layer may include a metal oxide and/or a metal fluoride including at least one of hafnium, zirconium, aluminum, tantalum, titanium, or yttrium. For example, the horizontal insulation layer 170 or the anti-reflection layer may include a first horizontal insulation layer including hafnium oxide, a second horizontal insulation layer including silicon oxide or silicon nitride, and a third horizontal insulation layer including hafnium oxide. However, example embodiments are not limited to thereto, and one or more of a number, a thickness, or so on of the layers included in the horizontal insulation layer 170 may be variously modified.

In example embodiments, the photoelectric conversion substrate 100 includes the horizontal insulation layer 170 on the first substrate surface 111. According to this, the horizontal insulation layer 170 is on the first surface 101 of the photoelectric conversion substrate 100 adjacent to the bonding layer 300, and thus, the horizontal insulation layer 170 may stably protect the substrate 110 including the photoelectric conversion portion 120 in a process of forming the bonding layer 300. The horizontal insulation layer 170 may be manufactured in a manufacturing process performed at relatively low temperature. Accordingly, even if the horizontal insulation layer 170 is on the substrate 110, unwanted effects on the substrate 110 including the photoelectric conversion portion 120 may be prevented or reduced in likelihood of occurrence and/or in impact from occurrence.

However, example embodiments are not limited thereto. In some example embodiments, the photoelectric conversion substrate 100 might not include the horizontal insulation layer 170, and the light receiving portion 200 may include the horizontal insulation layer 170.

The bonding layer 300 and the light receiving portion 200 may be on the first surface 101 of the photoelectric conversion substrate 100. The bonding layer 300 may bond the photoelectric conversion substrate 100 and the light receiving portion 200 between the photoelectric conversion substrate 100 and the light receiving portion 200. The bonding layer 300 will be described in more detail after describing the light receiving portion 200.

The light receiving portion 200 may include a light selection portion 210 and/or a lens portion 220, and may include a planarization layer 230. The light selection portion 210 may include any of various layers, films, members, or so on that separate light incident from the outside and transmit the light according to a wavelength downwardly. The light selection portion 210 may be referred to as an incoming signal converter, an incoming signal filter, an optical filter, or so on. The lens portion 220 may include any of various layers, films, members, or so on that improve light collection efficiency. The light receiving portion 200 (e.g., a first portion 200a) may include a pattern portion 200p having a pattern and the planarization layer 230 covering the pattern portion 200p to planarize a step such as a sharp step and/or a curve such as a gradual curve, that may be caused by the pattern portion 200p.

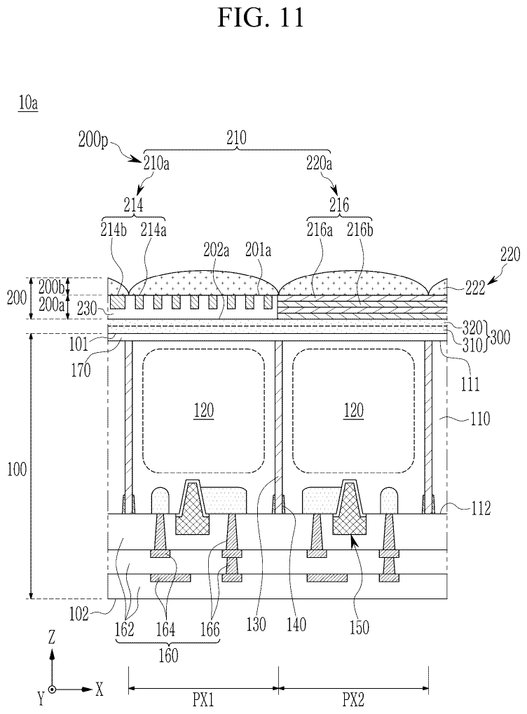

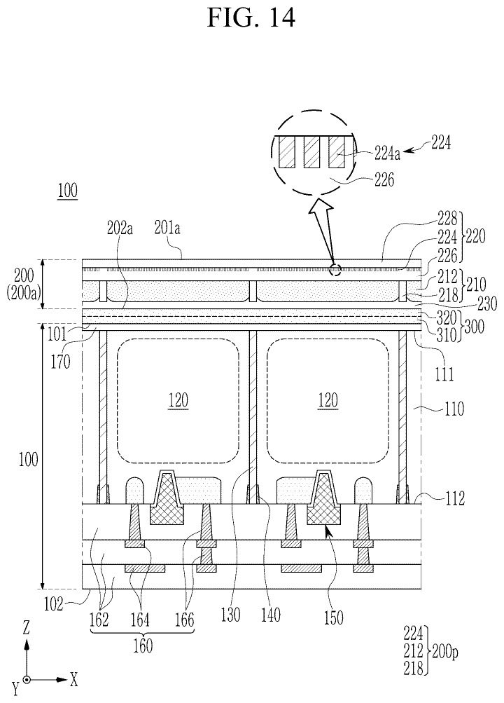

The light selection portion 210 may include at least one of a color filter 212, a filter separator 218, a polarization layer 214 (refer to FIG. 11), or a band pass filter 216 (ref to FIG. 11). The filter separator 218 is or includes a structure for forming the color filter 212 that separates light incident from the outside and transmits the light according to the wavelength downwardly. Accordingly, the filter separator 218 may be a part of the light selection portion 210. The lens portion 220 may include at least one of a micro lens 222 or a meta lens 224 (refer to FIG. 14).

In various example embodiments example embodiments, the light selection portion 210 may include the color filter 212 and/or the filter separator 218, and the lens portion 220 includes the micro lens 222. The polarization layer 214, the band pass filter 216, and the meta lens 224 will be described in more detail later.

A plurality of color filters 212 may include, for example, one or more than one of a green filter, a blue filter, and a red filter. In some example embodiments, the plurality of color filters 212 may include one or more than one of a white filter, a cyan filter, a magenta filter, or a yellow filter. In some example embodiments, the color filter 212 may further include an infrared filter for transmitting infrared light. The plurality of color filters 212 may be separated from each other by the filter separator 218.

In a plan view, the filter separator 218 may be disposed to overlap a partial portion of the pixel isolation portion 130. The filter separator 218 may be at a boundary of the color filter 212 and, for example, may surround at least a partial portion of the color filter 212. For example, the filter separator 218 may have the same or similar lattice structure as the pixel isolation portion 130, but example embodiments are not limited thereto. The filter separator 218 may be referred to as a fence pattern and/or a grid pattern.

The filter separator 218 may prevent or reduce light incident obliquely into one color filter 212 included in one of the plurality of pixel regions PX from entering another color filter 212 in another adjacent pixel region PX of the plurality of pixel regions PX. Accordingly, a crosstalk between the plurality of pixel regions PX may be prevented or reduced in likelihood of occurrence and/or in impact from occurrence.

In various example embodiments, the filter separator 218 may include a material having a refractive index smaller than a refractive index of the color filter 212 and/or silicon oxide, and/or a material having a refractive index of about 1.0 to about 1.4. When the filter separator 218 includes a material with a small refractive index in the above, the light incident on the filter separator 218 may be totally reflected and directed toward an inside of the pixel region PX.

For example, the filter separator 218 may include one or more of polymethyl methacrylate (PMMA), silicon acrylate, cellulose acetate butyrate (CAB), silica, or fluorine-silicon acrylate (FSA). For example, the filter separator 218 may include a polymer material in which silica particles are dispersed, in a homogenous manner and/or in a heterogenous manner. For example, the planarization layer 230 may include any one or more of various materials, such as, oxide (e.g., silicon oxide), nitride (e.g., silicon nitride), oxynitride (e.g., silicon oxynitride), a semiconductor material, an organic material, or so on. However, example embodiments are not limited to thereto, and the filter separator 218 and/or the planarization layer 230 may include a material different from the above material.

The micro lens 222 may be on the filter separator 218 and/or the color filter 212. The micro lens 222 may include a portion having a convex shape to converge or concentrate light incident to the pixel region PX. The micro lens 222 may include any one or more of various resin materials, for example, styrene-based resin, acryl-based resin, styrene-acryl copolymer resin, siloxane-based resin, or so on. However, example embodiments are not limited to thereto, and one or more of a shape, a material, or so on of the micro lens 222 may be variously modified.

In the drawings, it is illustrated that a plurality of micro lens 222 corresponds to a plurality of pixel regions PX, respectively. However, example embodiments are not limited to thereto, and one micro lens 222 may correspond to a plurality of pixel regions PX. In some example embodiments, a protective layer or so on may be further on an outer surface of the micro lens 222. In various example embodiments, the first portion 200a and the micro lens 222 may be in contact with each other, or an additional layer may be between the first portion 200a and the micro lens 222.

In various example embodiments, the light receiving portion 200 may include the first portion 200a. The first portion 200a may be formed separately from the photoelectric conversion substrate 100 in a state spaced apart from the photoelectric conversion substrate 100 and then be bonded to the photoelectric conversion substrate 100 by the bonding layer 300. In this instance, the first portion 200a may include the pattern portion 200p and the planarization layer 230. The light receiving portion 200 may further include a second portion 200b. The second portion 200b may be formed on the first portion 200a after the first portion 200a is bonded to the photoelectric conversion substrate 100.

Accordingly, in a manufacturing or fabrication process, the first portion 200a may be bonded to the photoelectric conversion substrate 100 in a state that an upper portion and a lower portion of the first portion 200a are reversed, and the second portion 200b may be formed by performing a process after the first portion 200a is bonded. Accordingly, the first portion 200a may have a reversed structure where the upper portion and the lower portion of the first portion 200a are reversed, and the second portion 200b may have a normal structure.

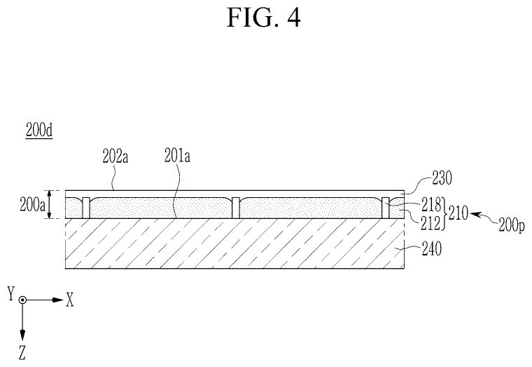

In the normal structure, an upper portion in a manufacturing process or a portion far away from a substrate (more particularly, a carrier substrate 240 (refer to FIG. 4)) is or corresponds to an upper portion of a final structure or is far away from the photoelectric conversion substrate 100 in the final structure. In the reverse structure, the upper portion in a manufacturing process or a portion far away from a substrate (more particularly, the carrier substrate 240) is or corresponds to a lower portion of a final structure or is closer to the photoelectric conversion substrate 100 in the final structure.

A first surface 201a (an upper surface in FIG. 3) of the first portion 200a, which is opposite to the photoelectric conversion substrate 100, may correspond to a lower surface or a base surface of the first surface 201a of the first portion 200a in a manufacturing process of the first portion 200a. A second surface 202a (a lower surface in FIG. 3) of the first portion 200a closer to the photoelectric conversion substrate 100 may correspond to an upper surface or a final surface of the first portion 200a in the manufacturing process of the first portion 200a. A portion of the first portion 200a closer to the first surface 201a of the first portion 200a may be formed earlier in the manufacturing process of the first portion 200a than another portion of the first portion 200a closer to the second surface 202a of the first portion 200a. The another portion of the first portion 200a closer to the second surface 202a of the first portion 200a may be formed later in the manufacturing process of the first portion 200a than the portion of the first portion 200a closer to the first surface 201a of the first portion 200a.

In various example embodiments, the first portion 200a may include the light selection portion 210 (e.g., the color filter 212 and/or the filter separator 218) and the planarization layer 230, and the second portion 200b may include the lens portion 220 (e.g., the micro lens 222).

For example, at least a partial portion of the light selection portion 210 (e.g., the color filter 212 and/or the filter separator 218) may correspond to the pattern portion 200p. In a plan view, the pattern portion 200p is in a partial portion of the light receiving portion 200 to have a predetermined pattern. In a cross-sectional view, the pattern portion 200p may have a shape that extends or protrudes from the first surface 201a of the first portion 200a toward the second surface 202a of the first portion 200a.

In various example embodiments, the pattern portion 200p may be at a side of the first surface 201a of the first portion 200a, which is opposite to the photoelectric conversion substrate 100, and the planarization layer 230 may be at a side of the second surface 202a of the first portion 200a closer to the photoelectric conversion substrate 100. For example, the pattern portion 200p may be adjacent to the first surface 201a of the first portion 200a, and may be spaced apart from the second surface 202a of the first portion 200a with at least the planarization layer 230 interposed therebetween. In a thickness direction (a Z-axis direction of the drawing) of the image sensor 10a, a distance between the second surface 202a of the first portion 200a and the pattern portion 200p may be greater than a distance between the first surface 201a of the first portion 200a and the pattern portion 200p.

In a cross-sectional view, a greater curve or step may be at a side of a second surface of the pattern portion 200p adjacent to the second surface 202a of the first portion 200a than a side of a first surface of the pattern portion 200p adjacent to the first surface 201a of the first portion 200a.

The planarization layer 230 may be on the second surface of the pattern portion 200p closer to the photoelectric conversion substrate 100 to cover the curve or step by the pattern portion 200p. A second surface of the planarization layer 230 adjacent to the second surface 202a of the first portion 200a or the photoelectric conversion substrate 100 may have a smaller curve or step than a first surface of the planarization layer 230 adjacent to the first surface 201a of the first portion 200a or the pattern portion 200p. For example, the second surface of the planarization layer 230 may have a flat surface.

In various example embodiments, in a cross-sectional view, the color filter 212 and/or the filter separator 218 may extend from the first surface 201a of the first portion 200a toward the second surface 202a of the first portion 200a, and may be spaced apart from the second surface 202a of the first portion 200a with at least the planarization layer 230 interposed therebetween.

For example, a first surface (an upper surface in FIG. 3) of the color filter 212 adjacent to the first surface 201a of the first portion 200a may be or may correspond to a flat surface or a level surface, and a second surface (a lower surface in FIG. 3) of the color filter 212 adjacent to the second surface 202a of the first portion 200a may be or may correspond to a curved and/or stepped surface or a rounded surface having a height difference in the thickness direction (the Z-axis direction in the drawing).

For example, a curve and/or step caused by a thickness of the filter separator 218 may be at a side of a second surface (a lower surface in FIG. 3) of the filter separator 218 adjacent to the second surface 202a of the first portion 200a. For example, a first surface (an upper surface in FIG. 3) of the filter separator 218 and the first surface (the upper surface in FIG. 3) of the color filter 212 adjacent to the first surface 201a of the first portion 200a may be a flat surface on the same plane, and the second surface (the lower surface in FIG. 3) of the filter separator 218 and the second surface (the lower surface in FIG. 3) of the color filter 212 adjacent to the second surface 202a of the first portion 200a may include portions having different heights to have a curved or stepped surface.

The planarization layer 230 may cover the other surface of the filter separator 218 and/or the color filter 212 adjacent to the second surface 202a of the first portion 200a. Accordingly, a first surface (an upper surface in FIG. 3) of the planarization layer 230 adjacent to the first surface 201a of the first portion 200a or the filter separator 218 and/or the color filter 212 may have a smaller curve or step than a second surface (a lower surface in FIG. 3) of the planarization layer 230 adjacent to the second surface 202a of the first portion 200a or the photoelectric conversion substrate 100. For example, the second surface of the planarization layer 230 may have a flat surface.

By the arrangement of the pattern portion 200p and the planarization layer 230, a shape of the pattern portion 200p, or so on, it may be seen that the pattern portion 200p is formed and the planarization layer 230 is formed to cover the pattern portion 200p in the manufacturing process of the first portion 200a, and then, a side of the first portion 200a where the planarization layer 230 is positioned is bonded to the photoelectric conversion substrate 100 by the bonding layer 300. In some examples, it may be seen that the first surface 201a of the first portion 200a may be a lower surface or a base surface, and a subsequent process is performed in a direction toward the second surface 202a of the first portion 200a in the process of forming the first portion 200a.

In various example embodiments, the micro lens 222 of the second portion 200b may have a shape that protrudes in a direction opposite to the photoelectric conversion substrate 100. For example, the micro lens 222 may have a shape that protrudes toward an outside. This is because the micro lens 222 is formed on the first surface 201a of the first portion 200a after bonding the first portion 200a.

As in the above, the pattern portion 200p (e.g., the filter separator 218 and/or the color filter 212) may be far away from the photoelectric conversion substrate 100, and the planarization layer 230 may be closer to the photoelectric conversion substrate 100 than the pattern portion 200p. Additionally or alternatively, the micro lens 222 may be adjacent to the pattern portion 200p and spaced apart from the planarization layer 230. For example, a flat bottom surface of the micro lens 222 may be adjacent to (e.g., in contact with) the pattern portion 200p. This is or may be different from the conventional structure in which a planarization layer is farther from a photoelectric conversion substrate than a filter separator and/or a color filter, and a micro lens is adjacent to the planarization layer.

In example embodiments, the light receiving portion 200 includes the micro lens 222 or the second portion 200b on the first portion 200a, but example embodiments are not limited thereto. The light receiving portion 200 may include the first portion 200a, but the light receiving portion 200 might not include the second portion 200b or the micro lens 222.

The bonding layer 300 between the photoelectric conversion substrate 100 and the light receiving portion 200 may bond the photoelectric conversion substrate 100 and the light receiving portion 200. For example, the bonding layer 300 may formed by bonding a first bonding layer 310 on the photoelectric conversion substrate 100 (e.g., on the first surface 101 of the photoelectric conversion substrate 100) and a second bonding layer 320 on the light receiving portion 200 (e.g., on the second surface 202a of the first portion 200a). For a clear understanding, an interface between the first bonding layer 310 and a second bonding layer 320 is illustrated as a dotted line in the drawing, but the interface between the first bonding layer 310 and the second bonding layer 320 may be seen or might not be seen in a final structure.

The first bonding layer 310 and the second bonding layer 320 may be bonded to each other by hydrophilicity or electrochemical affinity. For example, the first bonding layer 310 and the second bonding layer 320 may include a material capable of hydrophilic activation through a hydration process.

In various example embodiments, the bonding layer 300 (more particularly, the first bonding layer 310 or the second bonding layer 320) may include or be formed of silicon oxide (SiOx), silicon nitride (SiNx), silicon oxynitride (SiONx), silicon carbonitride (SiCNx), or so on. For example, the first bonding layer 310 and the second bonding layer 320 may be bonded by oxide interface bonding including oxide to form the bonding layer 300.

In various example embodiments, the bonding layer 300 (more particularly, the first bonding layer 310 or the second bonding layer 320) may include or be formed of an organic polymer or a carbon compound including a hydroxyl group, a carboxyl group, or so on. For example, the first bonding layer 310 or the second bonding layer 320 may be a polyester-based material or a polyamine-based material.

As described in the above, when the first bonding layer 310 and the second bonding layer 320 are bonded through the hydration process, the first bonding layer 310 and the second bonding layer 320 may have a simple structure and problems by mis-alignment may be prevented or reduced. For example, when the first bonding layer 310 and the second bonding layer 320 are formed by the oxide interface bonding using the hydration process, stability may be further improved.

For example, the first bonding layer 310 and the second bonding layer 320 may include the same material. Thereby, a process of forming the first bonding layer 310 and the second bonding layer 320 may be simplified. However, example embodiments are not limited thereto, and the first bonding layer 310 and the second bonding layer 320 may include different materials.

In various example embodiments, the bonding layer 300 may be distinguished from other layers by a material, a thickness, a shape, or so on. For example, when the bonding layer 300 includes the carbon compound, the bonding layer 300 may be distinguished from another layer (e.g., the horizontal insulation layer 170 or so on) by a material. In some example embodiments, a thickness of the bonding layer 300 may be greater than a thickness of a single layer included in the horizontal insulation layer 170 (e.g., an anti-reflection layer or a single layer included in the anti-reflection layer). As a result, bonding properties of the bonding layer 300 may be improved. However, example embodiments are not limited thereto, and the thickness of the bonding layer 300 may be the same or less than the thickness of a single layer included in the horizontal insulation layer 170 (e.g., an anti-reflection layer or a single layer included in the anti-reflection layer). In some example embodiments, the bonding layer 300 may have a substantially uniform thickness (e.g., a thickness having a difference within an error range of 10%) in an entire portion in a plan view. Thus, the bonding layer 300 may be distinguished from the pattern portion 200p, the planarization layer 230, or so on.

The image sensor 10a according to the embodiment may have a two-layer stacked structure in which the photoelectric conversion substrate 100 and at least a portion of the light receiving portion 200 (e.g., the first portion 200a) are manufactured separately and then bonded to each other. In example embodiments, the first portion 200a of the light receiving portion 200 is formed separately from the photoelectric conversion substrate 100, and restrictions on a material or a structure of the first portion 200a and process conditions (e.g., a manufacturing temperature) in the process of forming the first portion 200a may be minimized.

Therefore, optical properties of the image sensor 10a may be improved; alternatively or additionally, functions of the image sensor 10a may be expanded. For example, the first portion 200a may be manufactured to use invisible light or to receive light of a wide range of wavelengths to expand a receivable signal area. Therefore, the image sensor 10a may be applied to a multi-function image sensor and/or a modular image sensor (such as a customized image sensor). Since the image sensor 10a is small, portable, and convenient to use, the image sensor 10a may be applied to any of or more than one of various fields. Alternatively or additionally, a manufacturing process of the first portion 200a may be diversified, and/or available process conditions and/or process margins may be expanded.

On the other hand, if a light receiving portion was formed on a photoelectric conversion substrate as in the conventional art, a process that may undesirably change a structure and properties of the photoelectric conversion substrate and/or contaminate the photoelectric conversion substrate might not be used in a process of forming the light receiving portion. For example, it is difficult to use heat treatment processes performed at high temperatures. Therefore, there are many restrictions on a material or a structure of the light receiving portion and the process for forming the light receiving portion, and thus, types and functions of the light receiving portion are limited.

In various example embodiments, the color filter 212 may include a quantum dot 212a. The quantum dot 212a may emit light of various wavelengths due to a quantum confinement effect. The wavelength of light emitted from the quantum dot 212a may vary depending on a material, a size, or so on of the quantum dot 212a. For example, the quantum dot 212a may be a semiconductor particle including a semiconductor material. More particularly, the quantum dot 212a may be a semiconductor nanocrystal having a size of a nanometer level (e.g., 100 nm or less, more particularly, 1 nm to 30 nm).

In this instance, the quantum dot 212a in the color filter 212 may selectively transmit light of a predetermined wavelength or amplify light of a predetermined wavelength through the color filter 212. The light amplification through the quantum dot 212a may be implemented in any of various ways.

For example, the quantum dot 212a included in a green filter may selectively transmit green light or amplify green light. The quantum dot 212a included in a blue filter may selectively transmit blue light or amplify blue light. The quantum dot 212a included in a red filter may selectively transmit red light or amplify red light. The quantum dot 212a may selectively absorb light of ultraviolet wavelength or light of infrared wavelength and emit light of a desired wavelength to amplify light. The green filter, the blue filter, and the red filter described in the above are for illustrative purposes and example embodiments are not limited thereto. In some example embodiments, the quantum dot 212a may be provided only in at least one of a plurality of color filters 212 that transmit different colors. Various other modifications are possible.

In various example embodiments, the quantum dot 212a may include one or more of a two-dimensional carbon-based material, a metal oxide-based material, a group IV semiconductor, a group II-VI compound semiconductor, a group III-V compound semiconductor, or so on. In various example embodiments, the quantum dot 212a may include a two-dimensional carbon derivative, for example, a graphene-based quantum dot. As illustrated in an enlarged circle of FIG. 3, graphene is a material in which carbon atoms form a two-dimensional plane. The graphene-based quantum dot does not include a toxic material and may be stable to oxygen, moisture, heat, or so on.

However, example embodiments are not limited thereto, and the quantum dot 212a may have a core-shell structure. For example, the quantum dot 212a may include one or more of CdSe, CdS, CdTe, ZnSe, ZnS, InP, GaAs, GaP, GaN, InGaP, Si, CuZnS, or so on. The quantum dot 212a may have a spherical shape, but may have any of various other shapes. Alternatively or additionally, the shell layer surrounding the core layer may include a single layer or a plurality of layers.

The color filter 212 including the quantum dot 212a may have high light efficiency and/or may be convenient for color control to have high color reproducibility. Thus, optical properties of the image sensor 10a may be enhanced by the color filter 212 including the quantum dot 212a.

In the convention art, a color filter was formed of a photosensitive material due to limitations in a manufacturing process of the color filter. However, in various example embodiments, the color filter 212 is formed separately from the first portion 200a, and thus, the color filter 212 may include a desired material regardless of limitations in a manufacturing process. Accordingly, the color filter 212 including the quantum dot 212a may be stably formed, thereby improving a light efficiency of the color filter 212.

In example embodiments, the color filter 212 includes the quantum dot 212a. In some example embodiments, the color filter 212 may include any of various materials or additional materials that may improve properties and efficiency of the color filter 212. However, example embodiments are not limited thereto, and the color filter 212 may include a photosensitive material. Various other modifications are possible.

In the image sensor 10a according to various example embodiments, the light incident from the outside may be collected or concentrated by the micro lens 222 and incident on the photoelectric conversion portion 120 through the color filter 212. The light incident on the photoelectric conversion portion 120 may be converted into an electrical signal depending on an amount of the light.

According to various example embodiments, optical properties of the image sensor 10a may be improved and functions of the image sensor 10a may be expanded by reducing limitations in the manufacturing process of at least a partial portion of the light receiving portion 200 (e.g., the first portion 200a). Alternatively or additionally, the manufacturing process of at least the partial portion of the light receiving portion 200 (e.g., the first portion 200a) may be diversified, and available process conditions and process margins in the manufacturing process of at least the partial portion of the light receiving portion 200 may be expanded. Accordingly, the light receiving portion 200 or the image sensor 10a having enhanced properties and various functions may be formed through a suitable or optimized process.

A manufacturing method of the image sensor 10a will be described in more detail with reference to FIG. 4 to FIG. 8. To the extent that an element is not described in detail below, it may be understood that the element is at least similar to a corresponding element that has been described elsewhere within the present disclosure.

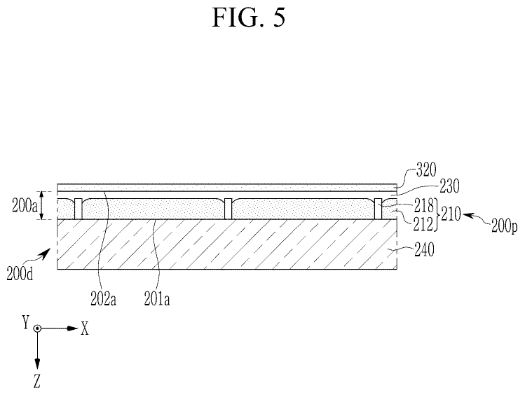

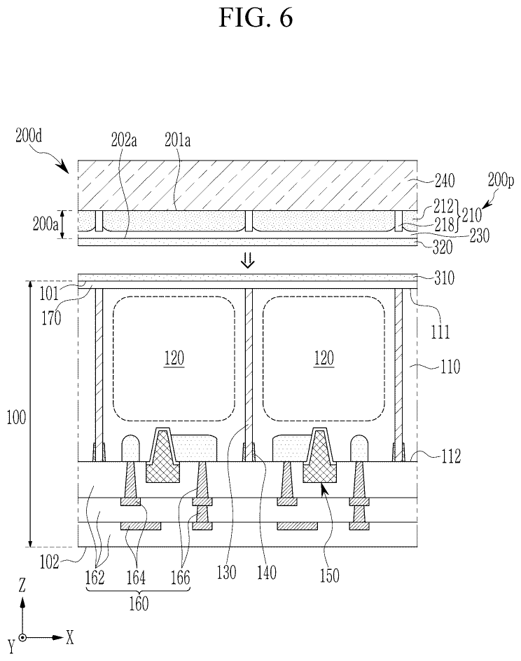

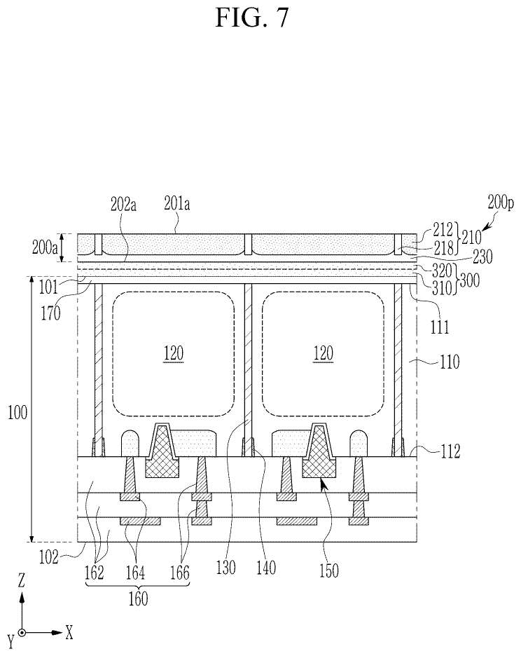

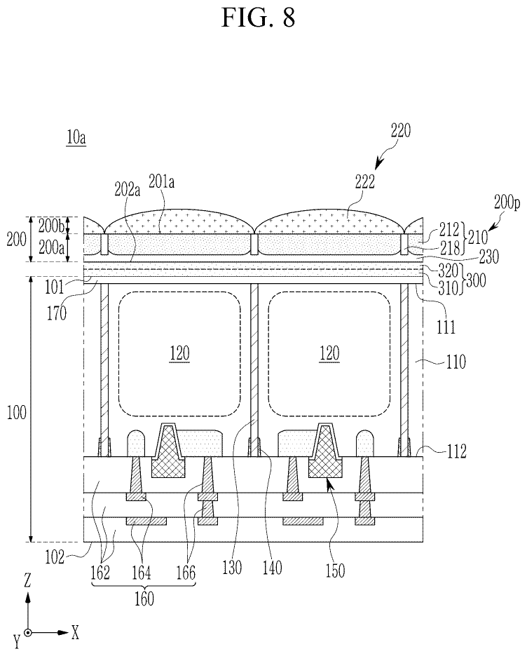

FIG. 4 to FIG. 8 are cross-sectional views schematically illustrating a manufacturing method of an image sensor 10a according to various example embodiments. In a manufacturing method of an image sensor 10a according to various example embodiments, a preliminary substrate 200d may be formed as illustrated in FIG. 4 and may be bonded to a photoelectric conversion substrate 100 as illustrated in FIG. 5 and FIG. 6. The preliminary substrate 200d may refer to a substrate including a carrier substrate 240 and at least a partial portion of a light receiving portion 200 (refer to FIG. 8) on the carrier substrate 240. Subsequently, a first portion 200a of the light receiving portion 200 may be formed by removing the carrier substrate 240 as illustrated in FIG. 7, and a subsequent process may be further performed as illustrated in FIG. 8. This will be described in more detail.

As illustrated in FIG. 4, the preliminary substrate 200d including the carrier substrate and at least the partial portion of the light receiving portion 200 on one surface of the carrier substrate 240 may be prepared. In this instance, the preparing of the preliminary substrate 200d may be performed separately from preparing of the photoelectric conversion substrate 100.

One surface of the carrier substrate 240 may correspond to a first surface 201a of the first portion 200a or a light selection portion 210. In various example embodiments, the first portion 200a may include the light selection portion 210 and a planarization layer 230, and the light selection portion 210 may include a filter separator 218 and a color filter 212.

In various example embodiments, the carrier substrate 240 may include any of various materials that supports the first portion 200a or the light selection portion 210 in the manufacturing process of the first portion 200a or the light selection portion 210 and is easily removed in a later process. For example, the carrier substrate 240 may be or may include a semiconductor substrate, more particularly, a silicon substrate. However, example embodiments are not limited to a material of the carrier substrate 240.

The first portion 200a may be formed on one surface (that is, the first surface 201a) of the carrier substrate 240. In various example embodiments, the light selection portion 210 including a pattern portion 200p (e.g., the filter separator 218 and the color filter 212) may be formed on one surface (e.g., the first surface 201a) of the carrier substrate 240, and then, the planarization layer 230 may be formed to cover the pattern portion 200p or the light selection portion 210. For example, the planarization layer 230 may cover a curve or step at a second surface of the pattern portion 200p (e.g., the filter separator 218 and the color filter 212).

The first surface 201a of the first portion 200a adjacent to the carrier substrate 240 may correspond to a lower surface or a base surface of the first portion 200a in the manufacturing process of the first portion 200a. A second surface 202a of the first portion 200a opposite to the first surface 201a of the first portion 200a may correspond to an upper surface or a final surface in the manufacturing process of the first portion 200a.

In various example embodiments, the light selection portion 210 (e.g., the filter separator 218 or the color filter 212) and the planarization layer 230 may be formed by any of various methods. The filter separator 218, the color filter 212, or the planarization layer 230 may be formed by any of various methods such as coating or deposition.

For example, the color filter 212 may include a quantum dot 212a (refer to FIG. 3). The color filter 212 including the quantum dot 212a may be formed by any of various methods. For example, the color filter layer 212 including the quantum dot 212a may be formed by applying a material (e.g., a solution) including the quantum dot 212a and then heat-treating (e.g., annealing) the material including the quantum dot 212a. In some example embodiments, the color filter 212 including the quantum dot 212a may be formed by deposition such as a plasma enhanced chemical vapor deposition and/or a low pressure vapor deposition and/or a sputter deposition. However, example embodiments are not limited thereto, and the color filter 212 might not include the quantum dots 212a.

The photoelectric conversion substrate 100 including the photoelectric conversion portion 120 may be prepared. In this instance, the photoelectric conversion substrate 100 including a portion except for the light receiving portion 200 may be prepared. Thereby, a bonding process of at least the partial portion of the light receiving portion 200 (e.g., the first portion 200a) and the photoelectric conversion substrate 100 is performed after the manufacturing process of the photoelectric conversion substrate 100. Accordingly, a process sequence may be maintained unchanged and a process may be easily performed. However, example embodiments are not limited thereto. In some example embodiments, a process of forming a partial portion of the photoelectric conversion substrate 100 may be further included after the bonding process of at least the partial portion of the light receiving portion 200 or a manufacturing process of another partial portion of the light receiving portion 200.

Subsequently, as illustrated in FIG. 5 and FIG. 6, a first bonding layer 310 may be formed on the photoelectric conversion substrate 100 and a second bonding layer 320 may be formed on the planarization layer 230, and then, the preliminary substrate 200d and the photoelectric conversion substrate 100 may be bonded by bonding the first bonding layer 310 and the second bonding layer 320.

For example, the first bonding layer 310 may be formed on a first surface 101 of the photoelectric conversion substrate 100. The first bonding layer 310 may be formed by any of various methods such as one or more of coating, deposition, or so on. In example embodiments, the first bonding layer 310 is formed on a horizontal insulation layer 170, but example embodiments are not limited thereto. For example, the second bonding layer 320 may be formed on an upper surface or a final surface of the first portion 200a (e.g., an upper surface or a final surface of the planarization layer 230). The second bonding layer 320 may be formed by any of various methods such as one or more of coating, deposition, or so on.

The preliminary substrate 200d may be positioned on the photoelectric conversion substrate 110 so that the first bonding layer 310 on the first surface 101 of the photoelectric conversion substrate 100 and the second bonding layer 320 on the preliminary substrate 200d face each other. In this instance, in the preliminary substrate 200d, the carrier substrate 240, the pattern portion 200p, or the first surface 201a may be far away from the photoelectric conversion substrate 100, and the planarization layer 230 or the second surface 202a may be closer to the photoelectric conversion substrate 100. That is, the preliminary substrate 200d may be positioned to have a reverse structure.

The first bonding layer 310 and the second bonding layer 320 may be bonded by applying heat and pressure while the first bonding layer 310 and the second bonding layer 320 are in contact with each other. In this instance, the bonding process of the first bonding layer 310 and the second bonding layer 320 may be performed through a hydration process, and a process temperature may be 250 degrees Celsius to 450 degrees Celsius. As such, the bonding process using the hydration process may be performed at a relatively low temperature, and unwanted changes in properties of the photoelectric conversion substrate 100 may be minimized. For example, the first bonding layer 310 and the second bonding layer 320 may include oxide (e.g., silicon oxide), and the first bonding layer 310 and the second bonding layer 320 may be bonded by oxide interface bonding.

Through the bonding process, the photoelectric conversion substrate 100 and the preliminary substrate 200d may be bonded by a bonding layer 300.

Subsequently, as illustrated in FIG. 7, the carrier substrate 240 (refer to FIG. 6) may be removed. The carrier substrate 240 may be removed by any of various methods. For example, the carrier substrate 240 may be removed by a grinding process performed at a side of a second surface (an upper surface in FIG. 6) of the carrier substrate 240. In some example embodiments, laser cutting may be performed at a side surface of the first portion 200a and the carrier substrate 240 to separate the first portion 200a and the carrier substrate 240. As a result, the first portion 200a may be formed.

Subsequently, as illustrated in FIG. 8, a subsequent process of forming a second portion 200b on the first portion 200a of the light receiving portion 200 or processing the first portion 200a may be further performed. In various example embodiments, the second portion 200b may be further formed on the first portion 200a, and the second portion 200b may include a micro lens 222. The micro lens 222 may be formed by any of various methods such as coating, deposition, or so on.

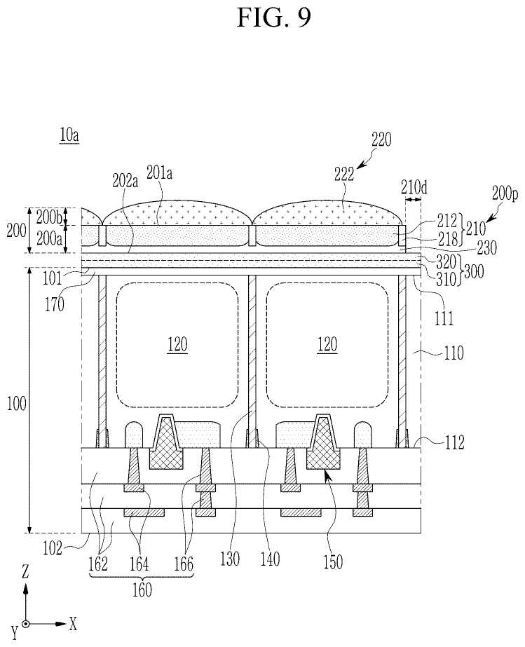

In some example embodiments, as illustrated in FIG. 9, a process of removing a partial portion of a first portion 200a may be performed in a subsequent process, and thus, the image sensor 10a may include a removed portion 210d where a partial portion of the first portion 200a is removed.

The process of removing the partial portion of the first portion 200a may be performed to remove the first portion 200a in an area (e.g., a dummy pixel region) where the first portion 200a is not needed or used. The process of removing the partial portion of the first portion 200a may be performed before or after a process of forming a second portion 200b. In some example embodiments a process of removing only a partial portion of the first portion 200a may be performed without a process of manufacturing the second portion 200b.

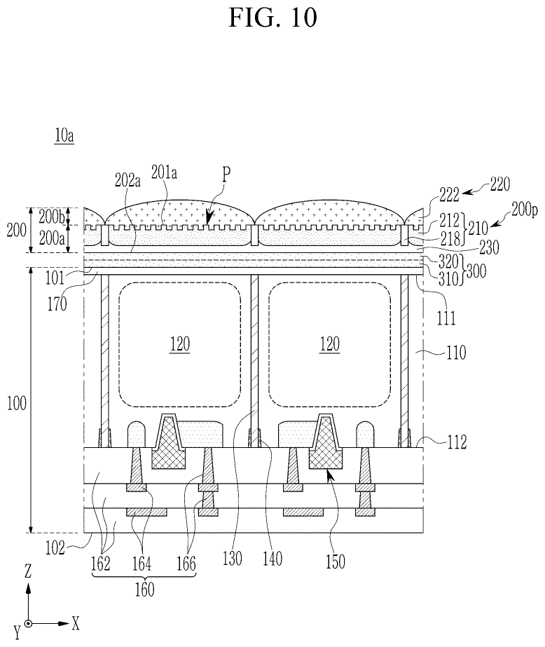

In some example embodiments, as illustrated in FIG. 10, a process of processing a first portion 200a or performing a surface treatment of the first portion 200a may be performed in a subsequent process. In FIG. 10, it is illustrated that a first surface 201a of the first portion 200a has an uneven portion P or a concavo-convex portion by a surface treatment. The uneven portion P of the first surface 201a may scatter light to improve optical properties or improve contact properties with the second portion 200b. It is illustrated that the uneven portion P has a cross-sectional shape of a rectangle in FIG. 10, but the uneven portion P may have an inclined surface or a rounded surface

The process of processing the first portion 200a or performing the surface treatment of the first portion 200a may be performed before the process of forming the second portion 200b. In some example embodiments, the process of processing the first portion 200a or performing the surface treatment of the first portion 200a may be performed without the process of forming the second portion 200b.

In FIG. 10, it is illustrated that a lens portion 220 or the micro lens 222 is in contact with the uneven P, but example embodiments are not limited thereto. An intermediate layer may be further formed on the uneven portion P, and the lens portion 220 or the micro lens 222 may be formed on the intermediate layer. Various other modifications are possible.

Hereinafter, an image sensor and a manufacturing method of an image sensor according to various example embodiments different from the above embodiment will be described in more detail with reference to FIG. 11 to FIG. 17. To the extent that an element is not described in detail below, it may be understood that the element is at least similar to a corresponding element that has been described elsewhere within the present disclosure.

FIG. 11 is a cross-sectional view schematically illustrating an image sensor according to various example embodiments.

Referring to FIG. 11, in various example embodiments, a first portion 200a may include a light selection portion 210 (e.g., a polarization layer 214 and/or a band pass filter 216) and a planarization layer 230, and a second portion 200b may include a lens portion 220 (e.g., a micro lens 222). For example, at least a partial portion of the light selection portion 210 (e.g., the polarization layer 214 and/or the band pass filter 216) may correspond to a pattern portion 200p.

In various example embodiments, in a cross-sectional view, the polarization layer 214 may extend or protrude from a first surface 201a of the first portion 200a toward a second surface 202a of the first portion 200a, and be spaced apart from the second surface 202a of the first portion 200a with the planarization layer 230 interposed therebetween. Accordingly, the polarization layer 214 may be at a side of the first surface 201a of the first portion 200a, and the planarization layer 230 may be at a side of the second surface 202a of the first portion 200a.

For example, a second surface (a lower surface in FIG. 3) of the polarization layer 214 adjacent to the second surface 202a of the first portion 200a may have with a curve or step due to a thickness of the polarization layer 214.

The planarization layer 230 may cover the second surface of the polarization layer 214 adjacent to the second surface 202a of the first portion 200a. Accordingly, the second surface 202a of the first portion 200a or the second surface (the lower surface in FIG. 3) of the planarization layer 230 adjacent to the photoelectric conversion substrate 100 may have a smaller curve or step than the first surface 201a of the first portion 200a or a first surface (an upper surface of FIG. 3) of the planarization layer 230 adjacent to the polarization layer 214. For example, the second surface of the planarization layer 230 may have a flat surface.

In various example embodiments, in a cross-sectional view, the band pass filter 216 may extend or protrude from the first surface 201a of the first portion 200a toward the second surface 202a of the first portion 200a. For example, in a plane including first and second pixel regions PX1 and PX2, a curve or step may be at a side of a second surface (a lower surface in FIG. 11) of the band pass filter 216 adjacent to the second surface 202a of the first portion 200a by a thickness of the band pass filter 216.

In FIG. 11, it is illustrated that the planarization layer 230 is not provided on the band pass filter 216 in the second pixel region PX2. This is because the second surface of the band pass filter 216 is a flat surface in the second pixel region PX2. According to this, a structure may be simplified. In some example embodiments, the planarization layer 230 of the first pixel region PX1 may cover the band pass filter 216 in the second pixel region PX2, or an additional planarization layer covering the band pass filter 216 may be included in the second pixel region PX2. In this instance, the band pass filter 216 may be at a side of the first surface 201a of the first portion 200a in the second pixel region PX2, and the planarization layer 230 or the additional planarization layer may be at a side of the second surface 202a of the first portion 200a.

In various example embodiments, the photoelectric conversion substrate 100 may include the first pixel region PX1 and the second pixel region PX2. The first portion 200a may include a first pixel portion 210a corresponding to the first pixel region PX1 and a second pixel portion 220a corresponding to the second pixel region PX2, and the first pixel portion 210a and the second pixel portion 220a may have different structures.

In various example embodiments, the first pixel portion 210a may transmit visible light (e.g., light of a predetermined wavelength range in the visible light) to be delivered to the first pixel region PX1, and the second pixel portion 201b may transmit invisible light (e.g., light of a predetermined wavelength range in the invisible light) to be delivered the second pixel region PX2. For example, the first pixel portion 210a may include a color filter 212 (refer to FIG. 3), a polarization layer 214, or so on, and the second pixel portion 220a may include a band pass filter 216. In FIG. 11, it is illustrated as an example that the first pixel portion 210a includes the polarization layer 214 and the second pixel portion 220a includes the band pass filter 216.

In example embodiments, the light receiving portion 200 including the first pixel portion 210a and the second pixel portion 220a having different structures and/or functions may be easily manufactured. On the other hand, in the conventional art, it was difficult to include a plurality of pixel portions with different structures and/or functions due to limitations in a manufacturing process.

In various example embodiments, the polarization layer 214 may include a plurality of polarization patterns having line shapes extending parallel to each other in each pixel region PX. For example, the polarization layer 214 may have a plurality of first line patterns 214a extending in parallel in one direction in one pixel region PX and a plurality of second line patterns 214b extending in a direction inclined at a certain angle to the one direction in another pixel region PX.

For example, the polarization layer 214 may include a conductive layer and a dielectric layer stacked on the first surface 201a of the first portion 200a. The conductive layer may include or be formed of a metal material such as tungsten, aluminum, titanium, tantalum, copper, or so on. The dielectric layer may include or be formed of an insulating material such as SiNx, SiONx, SiCx, SICNx, or SiCOx. In some example embodiments, the polarization layer 214 may include a first dielectric layer and a second dielectric layer that have different refractive indices and are sequentially stacked.

In the drawings, it is illustrated that the polarization layer 214 has a plurality of polarization patterns spaced apart from each other and the polarization patterns have rectangular cross-sectional shapes. However, example embodiments are not limited thereto, and the polarization layer 214 may have an inclined or rounded surface. In some example embodiments, the polarization layer 214 may have a layered shape including one or more layers on the first surface 201a of the first portion 200a.

The band pass filter 216 may have a multi-layered structure including a plurality of layers. For example, the band pass filter 216 may have a structure in which a first layer 216a with a relatively large refractive index and a second layer 216b with a refractive index lower than the refractive index of the first layer 216a are stacked. Transmittance of light of a desired wavelength may be controlled by adjusting an optical path difference according to thicknesses of the first layer 216a and the second layer 216b or a stacked structure of the first layer 216a and the second layer 216b. For example, the first layer 216a may include silicon and the second layer 216b may include silicon oxide, but the first layer 216a and the second layer 216b, or the band pass filter 216 may include any of various materials. In some example embodiments, one or more layers other than the first layer 216a and the second layer 216b may be further included.

In various example embodiments, the band pass filter 216 may transmit invisible light. For example, the band pass filter 216 may selectively transmit one or more of infrared rays (IR), near infrared rays (NIR), or ultraviolet rays (UV). However, example embodiments are not limited thereto, and the band pass filter 216 may selectively transmit visible light of a predetermined wavelength range.

In example embodiments, the first pixel portion 210a transmits the visible light, and the second pixel portion 220a transmits the invisible light. However, example embodiments are not limited thereto. For example, the first pixel portion 210a may transmit visible light of a predetermined wavelength range to be delivered to the first pixel region PX1, and the second pixel portion 220a may transmit visible light of another predetermined wavelength range to be delivered to the second pixel region PX2. In some example embodiments, the first pixel portion 210a may transmit invisible light of a predetermined wavelength range to be delivered to the first pixel region PX1, and the second pixel portion 220a may transmit invisible light of another predetermined wavelength range to be delivered to the second pixel region PX2.

In FIG. 11, it is illustrated as an example that the first pixel portion 210a includes the polarization layer 214 and the second pixel portion 220a includes the band pass filter 216, but example embodiments are not limited thereto. Various modifications are possible. For example, the first pixel portion 210a and the second pixel portion 220a may have different structures or include portions having different functions. In some example embodiments, the first portion 200a may further include an additional pixel portion having a different structure or function from the first and second pixel portions 210a and 220a.

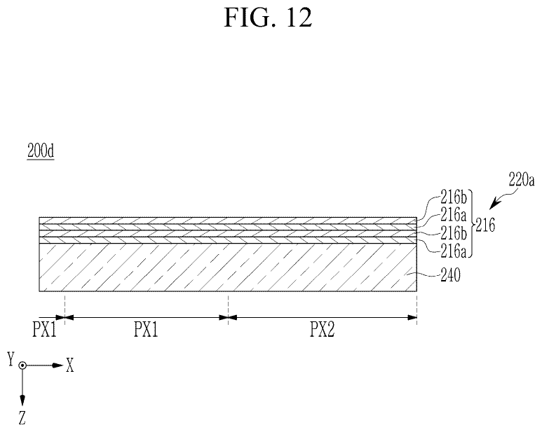

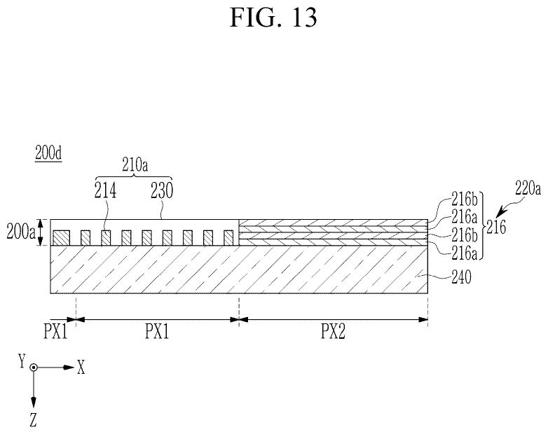

A manufacturing process of the preliminary substrate 200d included in the manufacturing method of the image sensor 10a will be described in more detail with reference to FIG. 12 and FIG. 13. To the extent that an element is not described in detail below, it may be understood that the element is at least similar to a corresponding element that has been described elsewhere within the present disclosure.

FIG. 12 and FIG. 13 are cross-sectional views schematically illustrating the manufacturing process of the preliminary substrate included in the manufacturing method of the image sensor illustrated in FIG. 11.

As illustrated in FIG. 12, the second pixel portion 220a may be formed entirely on one surface of the carrier substrate 240. For example, the band pass filter 216 may be formed entirely on one surface of the carrier substrate 240. The band pass filter 216 or the first layer 216a and second layer 216b included in the band pass filter 216 may be formed by any of various methods such as coating, deposition, or so on.

Subsequently, as illustrated in FIG. 13, a portion of the second pixel portion 220a corresponding to the first pixel region PX1 may be partially removed on one surface of the carrier substrate 240 and the first pixel portion 210a may be formed.

For example, the portion of the band pass filter 216 corresponding to the first pixel region PX1 may be removed. The process of partially removing the band pass filter 216 may be performed by a patterning process using a mask layer or a photo lithography process. The polarization layer 214 and the planarization layer 230 may be formed in a portion corresponding to the first pixel region PX1.

In FIG. 12 and FIG. 13, it is illustrated that the first pixel portion 210a includes the polarization layer 214 and the planarization layer 230, and the second pixel portion 220a includes the band pass filter 216. However, example embodiments are not limited thereto. A type or a kind of the light selection portion 210 included in the first and second pixel portions 210a and 220a may be variously modified, and the planarization layer 230 may be formed in both of the first and second pixel regions PX1 and PX2.

FIG. 14 is a cross-sectional view schematically illustrating an image sensor according to various example embodiments.

Referring to FIG. 14, a first portion 200a of a light receiving portion 200 may include a light selection portion 210 and a lens portion 220. In this instance, the lens portion 220 may be at a side of a first surface 201a of the first portion 200a, and the light selection portion 210 may be at a side of a second surface 202a of the first portion 200a.

In various example embodiments, the lens portion 220 may include a meta lens 224, which is a pattern portion 200p, and a planarization layer 226 covering the meta lens 224. In this instance, the meta lens 224 may be at a portion of the lens portion 220 adjacent to the first surface 201a of the first portion 200a, and the planarization layer 226 may be at a portion of the lens portion 220 adjacent to the second surface 202a of the first portion 200a. That is, at least a partial portion of the lens portion 220 may have a vertically inverted structure or a reverse structure when considering a manufacturing process. In some example embodiments, the lens portion 220 may further include a protective layer 228 on one surface of the meta lens 224 opposite to the planarization layer 226.

The meta lens 224 may include a nanostructure 224a having a nanorod or nanopillar shape with a nanometer-level size. In the meta lens 224, a meta-surface formed by periodically arranging meta atoms smaller than the wavelength of light may be included to change a direction of incident light to be directed to a specific point. As a result, the meta lens 224 may act as a lens. The meta lens 224 and/or nanostructure 224a may independently or concurrently include one or more of Si, SiN, GaN, TiO₂, or so on.

In this instance, the nanostructure 224a of the meta lens 224 may extend or protrude from the first surface 201a of the first portion 200a toward the second surface 202a of the first portion 200a. The nanostructure 224a of the meta lens 224 may be spaced apart from the second surface 202a of the first portion 200a or the light selection portion 210 with at least the planarization layer 226 interposed therebetween.

In various example embodiments, the light selection portion 210 may include a color filter 212 and a filter separator 218, which are pattern portions 200p, and a planarization layer 230 covering the color filter 212 and the filter separator 218. The description with reference to FIG. 3 may be applied to the light selection portion 210. However, example embodiments are not limited thereto. The light selection portion 210 may include a polarization layer 214 (refer to FIG. 11) and/or a band pass filter 216 (refer to FIG. 11). The description with reference to FIG. 11 may be applied to the light selection portion 210 including the polarization layer 214 and/or the band pass filter 216.

The protective layer 228 may cover a base surface or a lower surface (an upper surface in FIG. 14) of the meta lens 224. For example, the protective layer 228 may be formed in a process of forming a preliminary substrate. In some example embodiments, the protective layer 228 may include or be formed of at least a partial portion of a carrier substrate. In some example embodiments, the protective layer 228 may be formed after bonding the first portion 200a and removing a carrier substrate.

The preliminary substrate including the light selection portion 210 may be formed by sequentially forming the meta lens 224 and the planarization layer 226 on a carrier substrate to form the lens portion 220 and then forming the light selection portion 210 on the lens portion 220. The image sensor 10a may be formed by separately forming the preliminary substrate including the light selection portion 210 from a photoelectric conversion substrate 100, bonding the preliminary substrate including the light selection portion 210 and the photoelectric conversion substrate 100 using a bonding layer 300, and removing the carrier substrate.

When the protective layer 228 is formed in the process of forming the preliminary substrate, the protective layer 228 may be formed on the carrier substrate before forming the meta lens 224 and the planarization layer 226 on the carrier substrate. In some example embodiments, when the protective layer 228 is formed of at least a partial portion of the carrier substrate, the process of removing the carrier substrate might not be performed after the bonding process, or a process of reducing a thickness of the carrier substrate may be performed after the bonding process. In some example embodiments, the protective layer 228 may be formed after the bonding process and the process of removing the carrier substrate.

The meta lens 224 may be difficult to be formed on the photoelectric conversion substrate 100 since the meta lens 224 includes a fine pattern and may be formed by using a process performed at high temperature. According to various example embodiments, the light receiving portion 200 or the first portion 200a including the meta lens 224 may be formed separately from the photoelectric conversion substrate 100 and then be bonded to the photoelectric conversion substrate 100. Accordingly, the meta lens 224 may be applied to the image sensor 10a by forming the meta lens 224 under process conditions capable of forming the meta lens 224 and then bonding the meta lens 224 to the photoelectric conversion substrate 100.

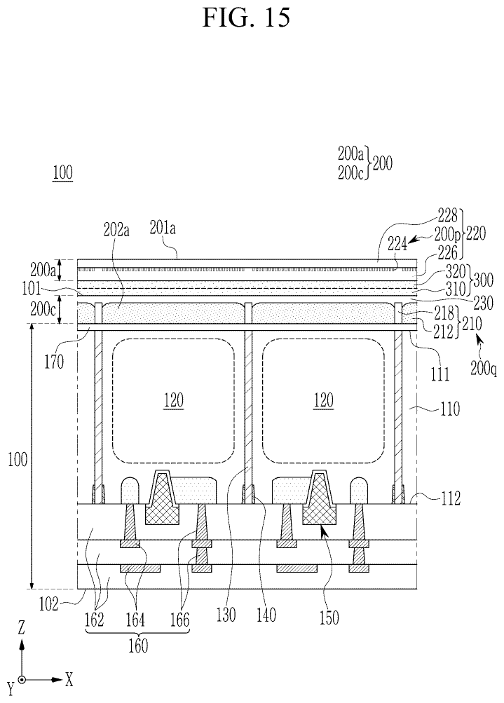

In example embodiments, it is illustrated that the first portion 200a includes the light selection portion 210 and the lens portion 220. However, example embodiments are not limited thereto. An embodiment different from the above will be described with reference to FIG. 15.

FIG. 15 is a cross-sectional view schematically illustrating an image sensor according to various example embodiments.

Referring to FIG. 15, a first portion 200a of a light receiving portion 200 may include a lens portion 220. The description with reference to FIG. 14 may be applied to a lens portion 220.

In various example embodiments, the light receiving portion 200 may further include a third portion 200c between a photoelectric conversion substrate 110 and a bonding layer 300 on the photoelectric conversion substrate 100. For example, the third portion 200c may include a light selection portion 210. In FIG. 15, it is illustrated that the third portion 200c or the light selection portion 210 includes a color filter 212 and a filter separator 218, and a planarization layer 230 covering the color filter 212 and the filter separator 218, but example embodiments are not limited thereto. The light selection portion 210 may include a polarization layer 214 (refer to FIG. 11) and/or a band pass filter 216 (refer to FIG. 11).

In this instance, a pattern portion 200q (e.g., the color filter 212, the filter separator 218, the polarization layer 214, and/or the band pass filter 216) of the third portion 200c may have a normal structure. That is, the pattern portion 200q of the third portion 200c (e.g., the color filter 212, the filter separator 218, the polarization layer 214, and/or the band pass filter 216) may be adjacent to the photoelectric conversion substrate 100 or may extend or protrude from a portion adjacent to the photoelectric conversion substrate 100 in a direction away from the photoelectric conversion substrate 100. The planarization layer 230 of the light selection portion 210 may be far away from the photoelectric conversion substrate 100.

Unless otherwise described, the description with reference to FIG. 3 or FIG. 11 may be applied to the light selection portion 210.

The preliminary substrate including the lens portion 220 may be formed by sequentially forming the meta lens 224 and a planarization layer 226 on a carrier substrate. The image sensor 10a may be formed by separately forming the preliminary substrate including the lens portion 220 from the photoelectric conversion substrate 100, bonding the preliminary substrate including the lens portion 220 and the photoelectric conversion substrate 100, on which the light selection portion 210 or the third portion 200c is positioned, using the bonding layer 300, and removing the carrier substrate.

When a protective layer 228 is formed in the process of forming the preliminary substrate, the protective layer 228 may be formed on the carrier substrate before forming the meta lens 224 and the planarization layer 226 on the carrier substrate. In some example embodiments, when the protective layer 228 is formed of at least a partial portion of the carrier substrate, the process of removing the carrier substrate might not be performed after the bonding process, or a process of reducing a thickness of the carrier substrate may be performed after the bonding process. In some example embodiments, the protective layer 228 may be formed after the bonding process and the process of removing the carrier substrate.

According to this, a manufacturing process of the photoelectric conversion substrate 100 including the photoelectric conversion portion 120 and the light selection portion 210 may be maintained unchanged. The lens portion 220 including the meta lens 224 may be formed separately and bonded.

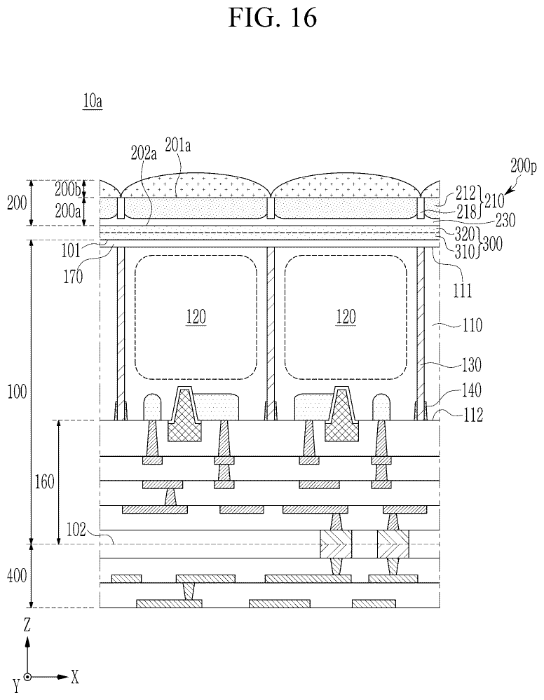

FIG. 16 is a cross-sectional view schematically illustrating an image sensor according to various example embodiments.

Referring to FIG. 16, an image sensor 10a according to various example embodiments may further include an additional wiring portion 400 bonded to the photoelectric conversion substrate 100 at a side of a second surface 102 of the photoelectric conversion substrate 100. According to this, the image sensor 10a may have a three-layer stacked structure including a light receiving portion 200, the photoelectric conversion substrate 100, and the additional wiring portion 400. In this instance, the wiring portion 160 and the additional wiring portion 400 may be bonded by hybrid bonding including metal bonding and insulating-layer bonding.

For example, the wiring portion 160 may include a wiring connected to a pixel circuit 150, and the additional wiring portion 400 may include one or more of circuit elements (e.g., transistors), a logic circuit, a power supply, a wiring, or so on. However, example embodiments are not limited thereto, and wirings, circuits, or so on included in the wiring portion 160 and the additional wiring portion 400 may be variously modified.

When the additional wiring portion 400 is further included as in the above, an arrangement of one or more of the wiring, the circuit elements, or so on included in the wiring portion 160 and the additional wiring portion 400 may be improved. As a result, an area of a pixel region of the image sensor 10a may be reduced to further improve an integration degree and properties of the image sensor 10a.

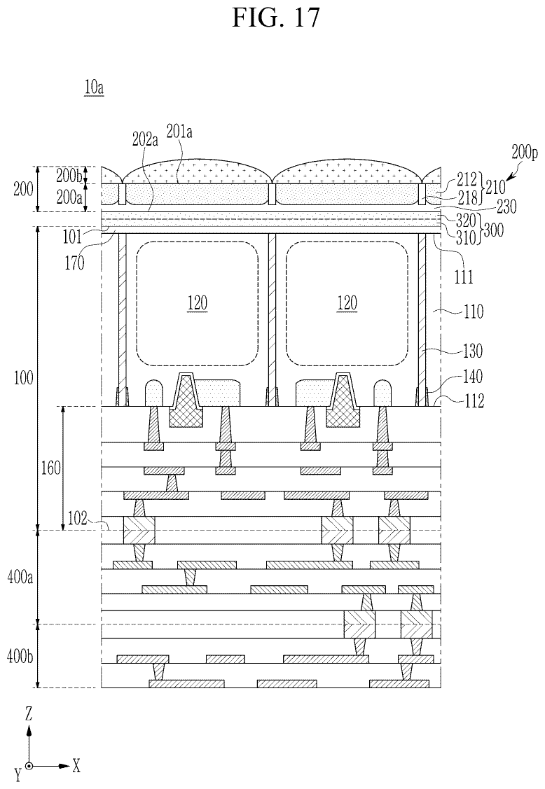

FIG. 17 is a cross-sectional view schematically illustrating an image sensor according to various example embodiments.

Referring to FIG. 17, in an image sensor 10a according to various example embodiments, first and second additional wiring portions 400a and 400b, which are bonded to a photoelectric conversion substrate 100 at a side of a second surface 102 of the photoelectric conversion substrate 100 may be further included. According to this, the image sensor 10a may have a four-layer stacked structure including a light receiving portion 200, the photoelectric conversion substrate 100, and the first and second additional wiring portions 400a and 400b. In this instance, the wiring portion 160 and the first additional wiring portion 400a may be bonded by hybrid bonding including metal bonding and insulating-layer bonding, and the first additional wiring portion 400a and the second additional wiring portion 400b may be bonded by hybrid bonding including metal bonding and insulating-layer bonding.

When the first and second additional wiring portions 400a and 400b are further included as in the above, an arrangement of a wiring, circuit elements, or so on included in the wiring portion 160 and the first and second additional wiring portion 400a and 400b may be improved. As a result, an area of a pixel region of the image sensor 10a may be reduced to further improve an integration degree and properties of the image sensor 10a.

For example, the wiring portion 160 may include a wiring connected to a pixel circuit 150, the first additional wiring portion 400a may include circuit elements (e.g., transistors), a wiring, or so on, and the second additional wiring portion 400b may include a logic circuit unit, a power supply unit, a wiring, or so on. However, example embodiments are not limited thereto, and wirings, circuits, or so on included in the wiring portion 160 and the first and second additional wiring portions 400a and 400b may be variously modified. In some example embodiments the image sensor 10a may further include another additional wiring portion other than the first and second additional wiring portions 400a and 400b.

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims. Furthermore, example embodiments are not necessarily mutually exclusive with one another. For example, some example embodiments may include one or more features described with reference to one or more figures, and may also include one or more other features described with reference to one or more other figures.

What is claimed is:

1. An image sensor, comprising:
a photoelectric conversion substrate including a photoelectric conversion portion;
a light receiving portion on a surface of the photoelectric conversion substrate; and
a bonding layer bonding the photoelectric conversion substrate and the light receiving portion between the photoelectric conversion substrate and the light receiving portion.

2. The image sensor of claim 1, wherein at least one of the bonding layer includes at least one of silicon oxide (SiOx), silicon nitride (SiNx), silicon oxynitride (SiONx), or silicon carbonitride (SiCNx), or the bonding layer includes a carbon compound including at least one of a hydroxyl group or a carboxyl group.

3. The image sensor of claim 1, wherein
at least one of the photoelectric conversion substrate or the light receiving portion further includes an anti-reflection layer, and
a thickness of the bonding layer is greater than a thickness of the anti-reflection layer.

4. An image sensor, comprising:
a photoelectric conversion substrate including a photoelectric conversion portion, and a light receiving portion on a surface of the photoelectric conversion substrate,
wherein the light receiving portion includes a first portion including a pattern portion and a planarization layer covering the pattern portion, and
the pattern portion is at a side of a first surface of the first portion opposite to the photoelectric conversion substrate, and the planarization layer is at a side of a second surface of the first portion closer to the photoelectric conversion substrate.

5. The image sensor of claim 4, wherein
the planarization layer covers at least one of a curve or a step by the pattern portion on a surface of the pattern portion closer to the photoelectric conversion substrate,
the planarization layer has a first surface closer to the pattern portion and a second surface closer to the photoelectric conversion substrate, and
the second surface of the planarization layer is flatter than the first surface of the planarization layer.

6. The image sensor of claim 4, wherein
the first portion includes a light selection portion including at least one of a color filter, a filter separator, a polarization layer, or a band pass filter, and
at least a partial portion of the light selection portion corresponds to the pattern portion.

7. The image sensor of claim 6, wherein
the light selection portion includes at least one of the color filter or the filter separator, and
the color filter or the filter separator at least one of extends or protrudes from the first surface of the first portion toward the second surface of the first portion, and is spaced apart from the second surface of the first portion with at least the planarization layer interposed therebetween.

8. The image sensor of claim 6, wherein the color filter includes a quantum dot.

9. The image sensor of claim 6, wherein
the light selection portion includes the polarization layer, and
the polarization layer at least one of extends or protrudes from the first surface of the first portion toward the second surface of the first portion, and is spaced apart from the second surface of the first portion with at least the planarization layer interposed therebetween.

10. The image sensor of claim 4, wherein
the first portion includes a meta lens, and
the meta lens corresponds to the pattern portion.

11. The image sensor of claim 10, wherein
the meta lens includes a nanostructure at least one of extending or protruding from the first surface of the first portion toward the second surface of the first portion, and
the nanostructure is spaced apart from the second surface of the first portion with at least the planarization layer interposed therebetween.

12. The image sensor of claim 10, wherein at least one of the first portion includes a lens portion including the meta lens, or the first portion includes the lens portion including the meta lens, and a light selection portion on a surface of the lens portion adjacent to the photoelectric conversion substrate.

13. The image sensor of claim 4, wherein
the light receiving portion further includes a second portion on the first portion, the second portion includes a micro lens protruding in a direction opposite to the photoelectric conversion substrate, and
a bottom surface of the micro lens is adjacent to the pattern portion.

14. The image sensor of claim 4, wherein
the photoelectric conversion substrate includes a first pixel region and a second pixel region,
the first portion includes a first pixel portion corresponding to the first pixel region and a second pixel portion corresponding to the second pixel region, and
the first pixel portion and the second pixel portion have different structures.

15. The image sensor of claim 14, wherein
the first pixel portion is configured to transmit visible light to be delivered to the first pixel region, and
the second pixel portion is configured to transmit invisible light to be delivered to the second pixel region.

16. The image sensor of claim 4, wherein the photoelectric conversion substrate includes a substrate including a plurality of pixel regions, the photoelectric conversion portion in the substrate, a pixel isolation portion defining the plurality of pixel regions, and a wiring portion at a side of another surface of the photoelectric conversion substrate opposite to the light receiving portion.

17. The image sensor of claim 4, further comprising:
a bonding layer that bonds the photoelectric conversion substrate and the light receiving portion between the photoelectric conversion substrate and the light receiving portion.

18. A manufacturing method of an image sensor, comprising:
preparing a preliminary substrate including a carrier substrate and at least a partial portion of a light receiving portion on the carrier substrate, and a photoelectric conversion substrate including a photoelectric conversion portion;
bonding the preliminary substrate and the photoelectric conversion substrate by forming a first bonding layer on the photoelectric conversion substrate, forming a second bonding layer on the preliminary substrate, and bonding the first bonding layer and the second bonding layer; and
removing the carrier substrate.

19. The manufacturing method of claim 18, wherein
at least one of (a) at least one of the first or second bonding layer includes at least one of silicon oxide (SiOx), silicon nitride (SiNx), silicon oxynitride (SiONx), or silicon carbonitride (SiCNx), or (b) at least one of the first or second bonding layer includes a carbon compound including at least one of a hydroxy group or a carboxyl group, and
in the bonding of the preliminary substrate and the photoelectric conversion substrate, the first bonding layer and the second bonding layer are bonded using a hydration process.

20. The manufacturing method of claim 18, wherein the preparing of the preliminary substrate is performed separately from the preparing of the photoelectric conversion substrate.
